(19) United States
(12) Patent Application Publication
(10) Pub. No.: US 2002/0041207 A1
(43) Pub. Date: Apr. 11, 2002

(54) Low noise amplification circuit of mobile communication terminal

(75) Inventor: Jae-Won Choi, Songnam-shi (KR)

Correspondence Address: Paul J. Farrell, Esq., DILWORTH & BARRESE, 333 Earle Ovington Boulevard, Uniondale, NY, 11553, US

(73) Assignee: Samsung Electronics Co., Ltd.

(21) Appl. No.: 09/734,854

(22) Filed: Feb. 28, 2001

(30) Foreign Application Priority Data
Dec. 13, 1999 (KR) 1999-57084

(51) Int. Cl. H03F 3/68

(52) U.S. Cl. 330/124 R

(57) ABSTRACT

Disclosed is a low noise amplification circuit of a mobile communication terminal having an antenna for receiving signals, comprising: a first hybrid for receiving a signal from the antenna, halving the power thereof, outputting a first signal, shifting the phase of the first signal, and outputting the phase shifted signal as a second signal; a first amplifier for receiving the first signal from the first hybrid, adjusting a reflection coefficient thereof, and outputting a signal having a desired low noise property; a second amplifier for receiving and amplifying the signal from the first amplifier; a third amplifier for receiving the second signal from the first hybrid, adjusting a reflection coefficient thereof, and outputting a signal having a desired low noise property; a fourth amplifier for receiving and amplifying the signal from the third amplifier; and a second hybrid for receiving the signals from the second and fourth amplifiers, coupling those components of the signal with the same phase, and outputting the coupled signal. According to the invention, a reflect coefficient can be reduced and a linearity can be improved in the low noise amplification circuit.

### PRIORITY

This application claims priority to an application entitled “Low Noise Amplifier Of Mobile Telephone” filed with the Korean Industrial Property Office on Dec. 13, 1999 and assigned Serial No. 1999-57084, the contents of which is hereby incorporated by reference.

### BACKGROUND OF THE INVENTION

1. Field of the Invention

The invention relates to a low noise amplification circuit of a mobile communication terminal, and in particular to a low noise amplification circuit having a low reflection coefficient and an improved linearity.

2. Description of the Related Art

A low noise amplification circuit of a mobile communication terminal of the prior art is comprised of a transistor as shown in FIG. 1A. Also shown in FIG. 1A are antenna ANT and mixer 110. Alternatively, several transistors (i.e. 101, 102 and 103) can be connected into a cascade to obtain a desired performance, as shown in FIG. 1B. Also shown inn FIG. 1B are antenna ANT and mixer 110.

However, the low noise amplification circuits of the prior art have problems in that the reflection coefficient is inversely proportional to the linearity of the amplifiers. Therefore, as the reflection coefficient decreases, the linearity deteriorates, and the alternative is also true, as the linearity improves, the reflection coefficient increases. Thus, a circuit does not exist in the prior art having ideal noise properties of a low reflection coefficient and good linearity.

### SUMMARY OF THE INVENTION

It is therefore an object of the invention to provide a low noise amplification circuit for a mobile communication terminal that has a low reflection coefficient.

It is another object of the invention to provide a low noise amplification circuit for a mobile communication terminal that has an improved linearity.

To obtain the objects of the present invention, there is provided a low noise amplification circuit of a mobile communication terminal having an antenna for receiving signals, comprising: a first hybrid for receiving a signal from the antenna, halving the power thereof, outputting a first signal, shifting the phase of the first signal, and outputting the phase shifted signal as a second signal; a first amplifier for receiving the first signal from the first hybrid, adjusting a reflection coefficient thereof, and outputting a signal having a desired low noise property; a second amplifier for receiving and amplifying the signal from the first amplifier; a third amplifier for receiving the second signal from the first hybrid, adjusting a reflection coefficient thereof, and outputting a signal having a desired low noise property; a fourth amplifier for receiving and amplifying the signal from the third amplifier; and a second hybrid for receiving the signals from the second and fourth amplifiers, coupling those components of the signal with the same phase, and outputting the coupled signal.

### BRIEF DESCRIPTION OF THE DRAWINGS

The above and other objects, features and advantages of the present invention will become more apparent from the following detailed description when taken in conjunction with the accompanying drawings in which:

FIG. 1A is a block diagram of a low noise amplification circuit of mobile communication terminals of the prior art;

FIG. 1B is a block diagram of a second low noise amplification circuit of mobile communication terminals of the prior art; and

FIG. 2 is a block diagram of a low noise amplification circuit according to an embodiment of the present invention.

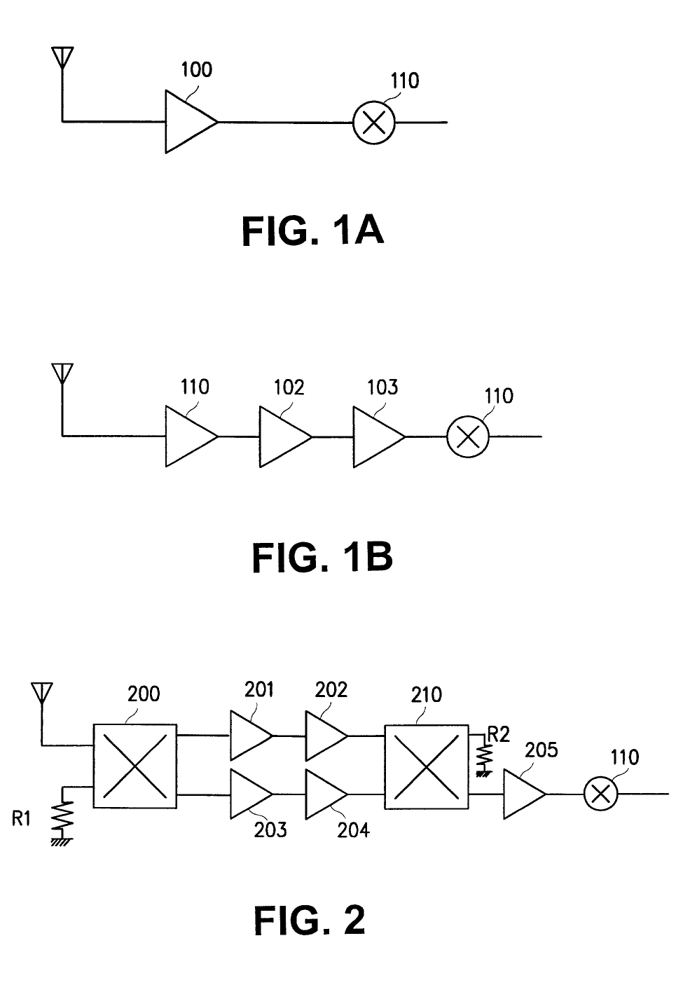

### DETAILED DESCRIPTION OF THE PREFERRED EMBODIMENT

Preferred embodiments of the present invention will be described herein below with reference to the accompanying drawings. In the following description, well-known functions or constructions are not described in detail since they would obscure the invention in unnecessary detail.

FIG. 2 is a block diagram of a low noise amplification circuit according to an embodiment of the present invention. Referring to FIG. 2, a first hybrid 200 receives an input signal Vᵢₙ via an antenna ANT. The first hybrid 200 halves the power, shifts the phase, and outputs two signals such that a first signal is defined by

$$\frac{Vin}{\sqrt{2}} < θ$$

and a second signal is defined by

$$\frac{Vin}{\sqrt{2}} < θ + 90 ° ,$$

where θ is the phase of the first signal received through the antenna. The output signals of the first hybrid are equal but phase shifted by 90 degrees. A first amplifier 201 receives the first signal from the first hybrid 200 and adjusts the signal to produce a signal with a low reflection coefficient. A second amplifier 202 receives a signal from the first amplifier 201. The second amplifier 202 amplifies the signal from the first amplifier 201. A third amplifier 203 receives the second signal from the first hybrid 200, and processes it such that a signal is output with desired a low noise property. A fourth amplifier 204 receives a signal from the third amplifier 203. The fourth amplifier 204 amplifies the signal from the third amplifier 203.

At this point, a phase shift of 180 degrees occurs between the signal reflected from the first amplifier 201 and the signal reflected form the second amplifier 202 so that the reflection wave reflected to the input end of the first hybrid 200 is zero. Therefore, the reflection coefficient of the mobile communication terminal according to the invention is advantageously reduced compared to that of the mobile communication terminal in the prior art. Also, the low noise amplification circuit of the mobile communication terminal according to this embodiment of the present invention amplifies each of the halved power signals such that the linearity is enhanced compared to the low noise amplifier of the mobile communication terminal in the prior art.

Finally, a second hybrid 210 receives the signals from the second amplifier 202 and from the fourth amplifier 204, couples those components of the signal with the same phase component, and outputs the coupled signal. A fifth amplifier 205 receives the signal from the second hybrid 210, amplifies the same and then outputs the amplified signal to a mixer 110. Resistors R1 and R2 are impedance matching resistors.

As described herein above according to an embodiment of the present invention, the reflection coefficient can be reduced and the linearity can be improved in the low noise amplification circuit of the mobile communication terminal.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A low noise amplification circuit of a mobile communication terminal having an antenna for receiving signals, comprising:
a first hybrid for receiving a signal from the antenna, halving the power thereof, outputting a first signal, and phase shifting said first signal and outputting said shifted signal as a second signal;
a first amplifier for receiving said first signal from said first hybrid, adjusting a reflection coefficient thereof and outputting a signal having a desired low noise property;
a second amplifier for receiving said signal from said first amplifier and amplifying said signal received from said first amplifier;
a third amplifier for receiving said second signal from said first hybrid, adjusting a reflection coefficient thereof and outputting a signal having a desired low noise property;
a fourth amplifier for receiving said signal from said third amplifier and amplifying said signal received from said third amplifier; and
a second hybrid for receiving said amplified signals from said second and fourth amplifiers and coupling components of said signals received from said second and fourth amplifiers having the same phase component, and outputting said coupled signal.

2. A low noise amplification circuit in accordance with claim 1, wherein said first and said second signals have a phase difference of 90 degrees.

3. A low noise amplification circuit in accordance with claim 1, further comprising a fifth amplifier for amplifying said signal from said second hybrid.
